(19) United States
(12) Patent Application Publication
(10) Pub. No.: US 2025/0309169 A1
(43) Pub. Date: Oct. 2, 2025

(54) PACKAGING STRUCTURE, ELECTRONIC DEVICE, AND PACKAGING METHOD

(71) Applicant: VIVO MOBILE COMMUNICATION CO., LTD., Dongguan (CN)

(72) Inventor: Dou JIN, Dongguan (CN)

(73) Assignee: VIVO MOBILE COMMUNICATION CO., LTD., Dongguan (CN)

(21) Appl. No.: 19/236,974

(22) Filed: Jun. 12, 2025

Related U.S. Application Data
(63) Continuation of application No. PCT/CN2023/138395, filed on Dec. 13, 2023.

(30) Foreign Application Priority Data
Dec. 16, 2022 (CN) 202211623125.0

(51) Int. Cl. H01L 23/00; H01L 23/31; H01L 23/498; H01L 25/00; H01L 25/04

(52) U.S. Cl. CPC H01L 24/16; H01L 23/3107; H01L 23/49816; H01L 24/13; H01L 25/04; H01L 25/50; H01L 24/32; H01L 24/73; H01L 2224/13111; H01L 2224/13147; H01L 2224/13611; H01L 2224/16145; H01L 2224/16225; H01L 2224/32145; H01L 2224/32225; H01L 2224/73204

(57) ABSTRACT

A packaging structure, an electronic device, and a packaging method are provided. The packaging structure includes a first packaging module and a second packaging module. The first packaging module includes a first die and a second die, the first die and the second die are arranged in a thickness direction of the first die, and the first die and the second die are electrically connected. The second packaging module and the first packaging module are arranged in the thickness direction, the second packaging module includes a third die and a fourth die, the third die and the fourth die are arranged in the thickness direction, and the third die and the fourth die are electrically connected. The fourth die and the first die are electrically connected.

### CROSS-REFERENCE TO RELATED APPLICATIONS

The application is a continuation of International Application No. PCT/CN2023/138395, filed on Dec. 13, 2023, which claims priority to Chinese Patent Application No. 202211623125.0, filed on Dec. 16, 2022. The entire contents of each of the above-referenced applications are expressly incorporated herein by reference.

### TECHNICAL FIELD

This application relates to the field of die packaging technologies, and specifically, to a packaging structure, an electronic device, and a packaging method.

### BACKGROUND

In a related technology, a plurality of dies may be arranged in a vertical direction when the plurality of dies are packaged. When the plurality of dies are arranged in a direction perpendicular to the die, adjacent dies are interconnected through a copper pillar, and the plurality of dies perform data transmission through the copper pillar. However, in such a die packaging structure, the copper pillar needs to occupy specific longitudinal space, so that a thickness of the packaging structure is relatively large.

### SUMMARY

This application provides a packaging structure, an electronic device, and a packaging method.

According to a first aspect, an embodiment of this application provides a packaging structure, including a first packaging module and a second packaging module. The first packaging module includes a first die and a second die, the first die and the second die are arranged in a thickness direction of the first die, and the first die and the second die are electrically connected. The second packaging module and the first packaging module are arranged in the thickness direction, the second packaging module includes a third die and a fourth die, the third die and the fourth die are arranged in the thickness direction, and the third die and the fourth die are electrically connected. The fourth die and the first die are electrically connected.

According to a second aspect, an embodiment of this application provides an electronic device, including the packaging structure in the first aspect.

According to a third aspect, an embodiment of this application provides a packaging method. The packaging method is used to package the packaging structure in the first aspect, and the packaging method includes: dicing a first wafer, to obtain a first die; arranging the first die on a substrate; dicing a second wafer, to obtain a second die; bonding the second die to the first die, to obtain a first packaging module; dicing a third wafer, to obtain a third die; bonding the third die to a fourth die on a fourth wafer; dicing the fourth wafer, to obtain a second packaging module; arranging the first packaging module and the second packaging module in a thickness direction; and electrically connecting the first die and the fourth die.

The packaging structure provided in this application includes the first packaging module and the second packaging module, the first packaging module includes the first die and the second die, the second packaging module includes the third die and the fourth die, the first die and the second die that are included in the first packaging module are bonded, the third die and the fourth die that are included in the second packaging module are bonded, and then the first packaging module and the second packaging module are connected, so that a plurality of dies in the packaging structure are modularized.

When the first packaging module and the second packaging module are connected, the first packaging module and the second packaging module may be connected through the first die and the fourth die on two sides in a vertical direction, to implement an electrical connection between the first packaging module and the second packaging module. When the first die and the fourth die are bonded, an electrical connection part between the first die and the fourth die may occupy space in which the second die and the third die are located, and no electrical connection part needs to be disposed between the second die and the third die, to reduce occupation of longitudinal space by an electrical connection part between the first packaging module and the second packaging module, reduce a thickness of a packaging module, reduce occupation of longitudinal space by the packaging module, and help lighten and thin the packaging module.

The electronic device provided in this application includes the foregoing packaging structure. The packaging method provided in this application is used to manufacture the foregoing packaging structure. Therefore, the electronic device and the packaging method provided in this application have a beneficial effect of the foregoing packaging structure.

Additional aspects and advantages of this application are partially provided in the following descriptions, and partially become clear from the following descriptions, or are learned from practice of this application.

### BRIEF DESCRIPTION OF DRAWINGS

The foregoing and/or additional aspects and advantages of this application become clear and readily understood from the descriptions of embodiments with reference to the following accompanying drawings.

FIG. 1 is a schematic diagram 1 of a packaging structure according to an embodiment of this application;

FIG. 2 is a schematic diagram 1 of a packaging process of a packaging structure according to an embodiment of this application;

FIG. 3 is a schematic diagram 2 of a packaging process of a packaging structure according to an embodiment of this application;

FIG. 4 is a schematic diagram 3 of a packaging process of a packaging structure according to an embodiment of this application;

FIG. 5 is a schematic diagram 2 of a packaging structure according to an embodiment of this application;

FIG. 6 is a schematic diagram 4 of a packaging process of a packaging structure according to an embodiment of this application;

FIG. 7 is a schematic diagram 5 of a packaging process of a packaging structure according to an embodiment of this application;

FIG. 8 is a schematic diagram 6 of a packaging process of a packaging structure according to an embodiment of this application;

FIG. 9 is a schematic diagram 7 of a packaging process of a packaging structure according to an embodiment of this application;

FIG. 10 is a schematic diagram 8 of a packaging process of a packaging structure according to an embodiment of this application;

FIG. 11 is a schematic diagram 9 of a packaging process of a packaging structure according to an embodiment of this application;

FIG. 12 is a schematic diagram 10 of a packaging process of a packaging structure according to an embodiment of this application;

FIG. 13 is a schematic diagram 11 of a packaging process of a packaging structure according to an embodiment of this application; and

FIG. 14 is a flowchart of a packaging method according to an embodiment of this application.

### REFERENCE NUMERALS

100: First packaging module; 110: First die; 120: Second die; 200: Second packaging module; 210: Third die; 220: Fourth die; 302: First metal ball; 304: First dielectric layer; 306: First wiring layer; 308: First bump; 310: Second bump; 312: Second metal ball; 314: Second dielectric layer; 316: Second wiring layer; 318: Third metal ball; 320: Third dielectric layer; 322: Third wiring layer; 324: Third bump; 326: Fourth bump; 328: Packaging part; 330: First colloid; 332: Second colloid; 334: Fifth bump; 336: Fourth dielectric layer; 338: Substrate; 340: First wafer; 342: Second wafer; 344: Third wafer; 346: Fourth wafer; and 348: Attach film.

### DETAILED DESCRIPTION

The following describes in detail embodiments of this application, and examples of embodiments are shown in the accompanying drawings. Throughout identical or similar reference numerals represent identical or similar elements or elements having identical or similar functions. Embodiments described below with reference to the accompanying drawings are examples and are intended to explain this application only, but are not construed as a limitation on this application. All other embodiments obtained by a person of ordinary skill in the art based on embodiments of this application without creative efforts shall fall within the protection scope of this application.

Features of terms “first” and “second” in the specification and claims of this application may explicitly or implicitly include one or more such features. In the descriptions of this application, unless otherwise stated, “a plurality of” means two or more than two. In addition, in the specification and claims, “and/or” represents at least one of the connected objects, and the character “/” usually represents an “or” relationship between associated objects.

In the descriptions of this application, it should be understood that orientation or position relationships indicated by the terms “center”, “longitudinal”, “horizontal”, “length”, “width”, “thickness”, “upper”, “lower”, “front”, “back”, “left”, “right”, “vertical”, “horizontal”, “top”, “bottom”, “inside”, “outside”, “clockwise”, “counter-clockwise”, “axial”, “radial”, “circumferential”, and the like are based on orientation or position relationships shown in the accompanying drawings, and are merely intended for ease of describing this application and simplifying descriptions, rather than indicating or implying that an indicated apparatus or element needs to have a specific orientation or needs to be constructed and operated in a specific orientation. Therefore, such terms cannot be understood as a limitation on this application.

In the descriptions of this application, it should be noted that, unless otherwise specified and limited, the terms “mounting”, “interconnection”, and “connection” should be understood in a broad sense. For example, the term “connection” may be a fixed connection, a detachable connection, or an integrated connection; or may be a mechanical institution or an electrical connection; or may be a direct connection, an indirect connection by using an intermediate medium, or an internal connection of two elements. A person of ordinary skill in the art may understood specific meanings of the terms in this application based on specific cases.

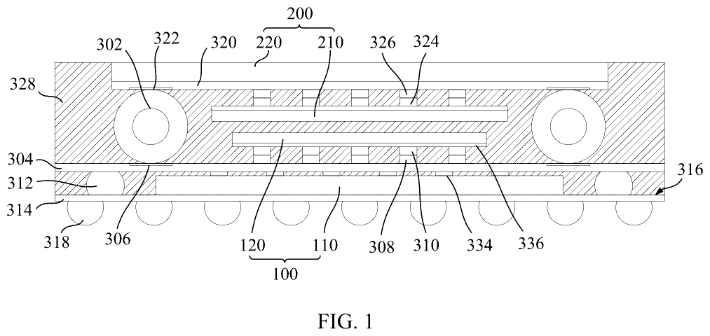

The following describes a packaging structure, an electronic device, and a packaging method according to embodiments of this application with reference to FIG. 1 to FIG. 14.

As shown in FIG. 1, a packaging structure according to some embodiments of this application includes a first packaging module 100 and a second packaging module 200. The first packaging module 100 includes a first die 110 and a second die 120, the first die 110 and the second die 120 are arranged in a thickness direction of the first die 110, and the first die 110 and the second die 120 are electrically connected. The second packaging module 200 and the first packaging module 100 are arranged in the thickness direction, the second packaging module 200 includes a third die 210 and a fourth die 220, the third die 210 and the fourth die 220 are arranged in the thickness direction, and the third die 210 and the fourth die 220 are electrically connected. The fourth die 220 and the first die 110 are electrically connected.

In this embodiment, the packaging structure includes the first packaging module 100 and the second packaging module 200, the first packaging module 100 includes the first die 110 and the second die 120, the second packaging module 200 includes the third die 210 and the fourth die 220, the first die 110 and the second die 120 that are included in the first packaging module 100 are bonded, the third die 210 and the fourth die 220 that are included in the second packaging module 200 are bonded, and then the first packaging module 100 and the second packaging module 200 are connected, so that a plurality of dies in the packaging structure are modularized.

When the first packaging module 100 and the second packaging module 200 are connected, the first packaging module 100 and the second packaging module 200 may be connected through the first die 110 and the fourth die 220 on two sides in a vertical direction, to implement an electrical connection between the first packaging module 100 and the second packaging module 200. When the first die 110 and the fourth die 220 are bonded, an electrical connection part between the first die 110 and the fourth die 220 may occupy space in which the second die 120 and the third die 210 are located, and no electrical connection part needs to be disposed between the second die 120 and the third die 210, to reduce occupation of longitudinal space by an electrical connection part between the first packaging module 100 and the second packaging module 200, reduce a thickness of a packaging module, reduce occupation of longitudinal space by the packaging module, and help lighten and thin the packaging module.

For example, in a longitudinal direction, the first die 110, the second die 120, the third die 210, and the fourth die 220 are sequentially arranged. The first die 110, the second die 120, the third die 210, and the fourth die 220 are arranged in the longitudinal direction, so that a signal transfer path between dies is shorter, and a transfer speed is higher, to further improve performance of the packaging module.

Further, the packaging structure may further include a third packaging module. The third packaging module may include a fifth die and a sixth die. The fifth die and the sixth die are electrically connected, and the sixth die and the fourth die 220 are electrically connected.

The packaging structure may further include a fourth packaging module or more packaging modules.

Further, the first packaging module 100 may further include a seventh die, the seventh die and the second die 120 are electrically connected, and the first packaging module 100 may further include more dies.

The second packaging module 200 may further include a die other than the third die 210 and the fourth die 220. For example, the second packaging module 200 includes three dies or four dies.

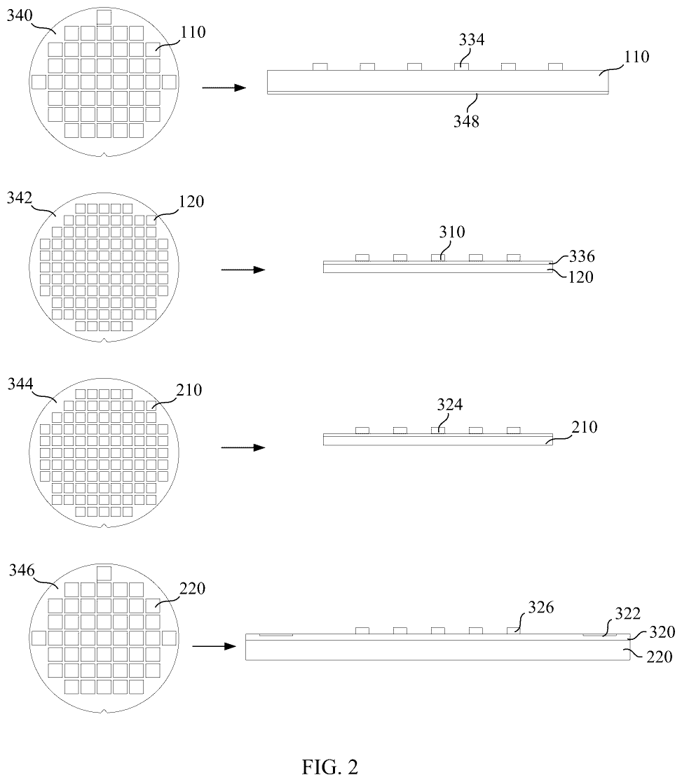

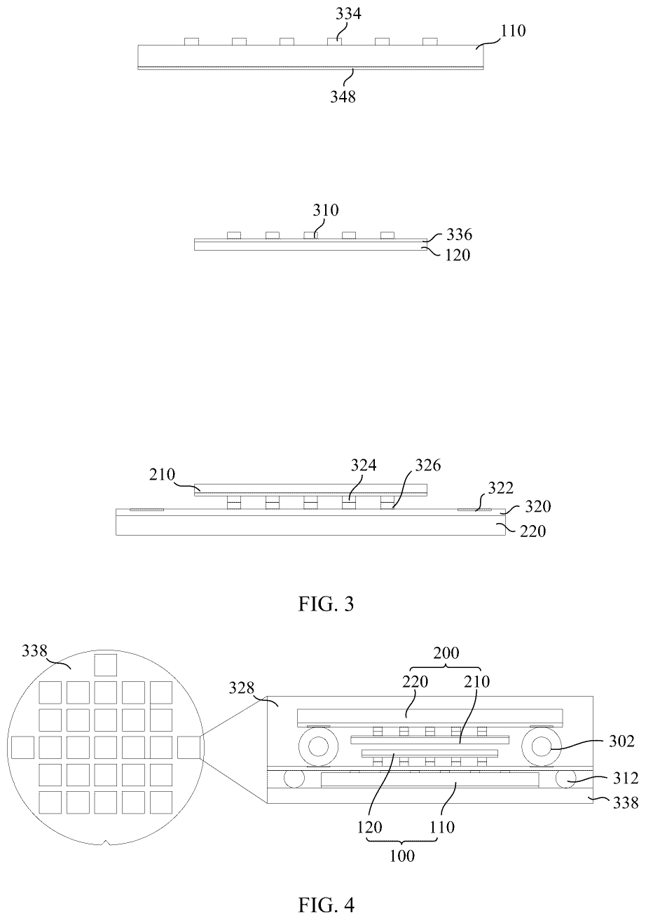

For example, as shown in FIG. 2, when the packaging structure is packaged, a first wafer 340 and a second wafer 342 are first diced, to obtain the first die 110 and the second die 120, and a third wafer 344 is diced, to obtain the third die 210. As shown in FIG. 3, the third die 210 is bonded to the fourth die 220 in a wafer state, and after bonding, a fourth wafer 346 is diced, to obtain the second packaging module 200. As shown in FIG. 4, the first die 110 and the second die 120 are bonded, to obtain the first packaging module 100, and then the first packaging module 100 and the second packaging module 200 are electrically connected, to obtain the packaging structure.

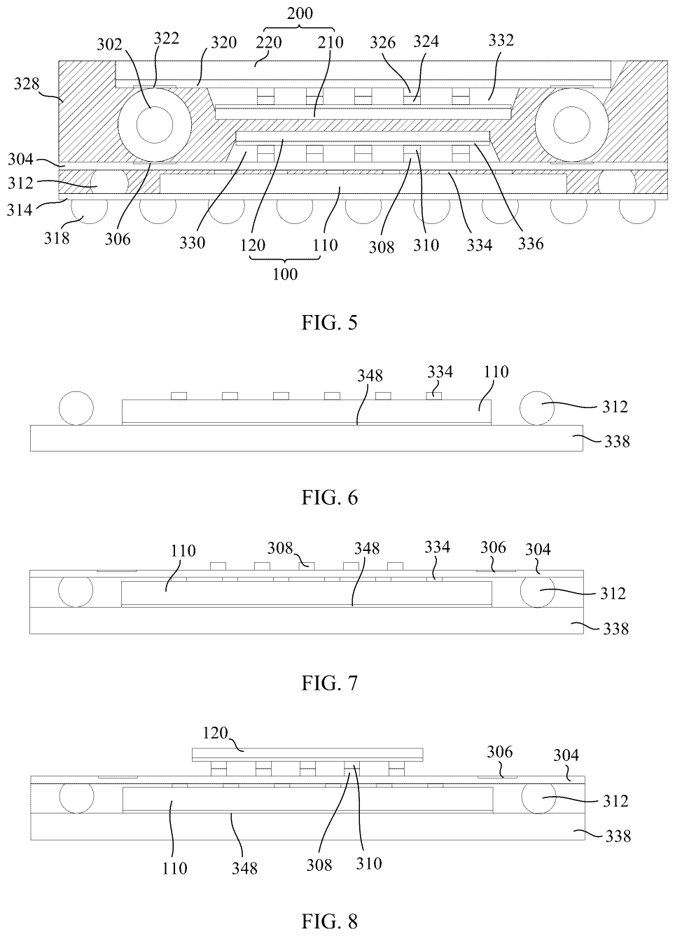

According to some embodiments of this application, as shown in FIG. 1 and FIG. 5, the packaging structure further includes a first metal ball 302. A first side of the first metal ball 302 is connected to the first die 110, and a second side is connected to the fourth die 220. The first side of the first metal ball 302 and the second side of the first metal ball 302 are two sides that are opposite in the thickness direction.

In this embodiment, the first die 110 and the fourth die 220 are connected through the first metal ball 302. The first metal ball 302 may be produced in batches as a separate part. In a process of bonding the first die 110 and the fourth die 220, the first metal ball 302 is fastened to the packaging structure, without a need to manufacture an electrical connection part such as a copper pillar in the packaging structure by using a process such as plating, to simplify a packaging process of the packaging structure, and reduce manufacturing difficulty of the packaging structure. In addition, the first metal ball 302 may be separately produced in batches, without a need to occupy a processing time of the packaging structure, to increase a manufacturing speed of the packaging structure, and improve production efficiency of the packaging structure. The first metal ball 302 produced in batches may further reduce material costs and process costs of the packaging structure.

According to some embodiments of this application, as shown in FIG. 1 and FIG. 5, the packaging structure further includes a first dielectric layer 304 and a first wiring layer 306. The first dielectric layer 304 is disposed between the first die 110 and the second die 120. The first wiring layer 306 is disposed at the first dielectric layer 304, and is electrically connected to the first metal ball 302 and the first die 110.

In this embodiment, the first dielectric layer 304 is located between the first die 110 and the second die 120, the first wiring layer 306 is disposed at the first dielectric layer 304, the first wiring layer 306 and the first metal ball 302 are electrically connected, and the first wiring layer 306 and the first die 110 are electrically connected, to implement an electrical connection between the first metal ball 302 and the first die 110, so that the first die 110 can transfer data to the fourth die 220 through the first metal ball 302.

Further, a pad is disposed at the first wiring layer 306, and the first metal ball 302 is soldered onto the pad at the first wiring layer 306, to implement a connection between the first wiring layer 306 and the first metal ball 302, and mounting and positioning of the first metal ball 302 by the first wiring layer 306.

According to some embodiments of this application, as shown in FIG. 1 and FIG. 5, the packaging structure further includes a first bump 308 and a second bump 310. The first bump 308 is disposed on a side that is of the first dielectric layer 304 and that is close to the second die 120, and is electrically connected to the first wiring layer 306. The second bump 310 is disposed on a side that is of the second die 120 and that is close to the first die 110, is electrically connected to the second die 120, and is in contact with the first bump 308.

In this embodiment, the first bump 308 is disposed on the side that is of the first dielectric layer 304 and that is close to the second die 120, and is electrically connected to the first wiring layer 306, so that the first bump 308 is electrically connected to the first die 110 through the first wiring layer 306. The second bump 310 is disposed on the side that is of the second die 120 and that is close to the first die 110, is electrically connected to the second die 120, and is in contact with the first bump 308, to implement bonding between the first die 110 and the second die 120, and implement signal transfer between the first die 110 and the second die 120.

Further, the first bump 308 and the second bump 310 may be micro-bumps, or may be copper pillars.

Further, the packaging structure further includes a fifth bump 334. The fifth bump 334 is disposed on a side that is of the first die 110 and that is close to the first dielectric layer 304, and is connected to the first wiring layer 306.

An attach film 348 is further disposed on a side that is of the first die 110 and that is away from the first dielectric layer 304, so that the first die 110 is bonded to a substrate 338, to implement wafer reconstruction.

Further, the packaging structure further includes a fourth dielectric layer 336, and the fourth dielectric layer 336 is disposed between the second bump 310 and the second die 120.

According to some embodiments of this application, as shown in FIG. 1 and FIG. 5, the packaging structure further includes a second metal ball 312, a second dielectric layer 314, a second wiring layer 316, and a third metal ball 318. The second metal ball 312 is disposed on a side that is of the first dielectric layer 304 and that is close to the first die 110, and is electrically connected to the first wiring layer 306. The second dielectric layer 314 is disposed on a side that is of the first die 110 and that is away from the second die 120. The second wiring layer 316 is disposed at the second dielectric layer 314, and is electrically connected to the second metal ball 312. The third metal ball 318 is disposed on a side that is of the second dielectric layer 314 and that is away from the first die 110, and is electrically connected to the second dielectric layer 314.

In this embodiment, the second metal ball 312 is disposed on the side that is of the first dielectric layer 304 and that is close to the first die 110, and is electrically connected to the first wiring layer 306, so that the second metal ball 312 is electrically connected to the first die 110 through the first wiring layer 306. The second dielectric layer 314 is disposed on the side that is of the first die 110 and that is away from the second die 120. The second wiring layer 316 is disposed at the second dielectric layer 314, and the second wiring layer 316 and the second metal ball 312 are electrically connected, so that the second wiring layer 316 can be electrically connected to the first die 110. The third metal ball 318 is disposed on the side that is of the second dielectric layer 314 and that is away from the first die 110, and the third metal ball 318 is electrically connected to the second dielectric layer 314, so that the third metal ball 318 can be connected to the first die 110, and the first die 110 can transfer data through the third metal ball 318.

Further, there are a plurality of third metal balls 318, and the plurality of third metal balls 318 are arranged in an array on the side that is of the second dielectric layer 314 and that is away from the first die 110, to serve as pins of the packaging structure.

According to some embodiments of this application, as shown in FIG. 1 and FIG. 5, at least one of the first metal ball 302, the second metal ball 312, and the third metal ball 318 is a copper ball; or at least one of the first metal ball 302, the second metal ball 312, and the third metal ball 318 is a tin ball; or at least one of the first metal ball 302, the second metal ball 312, and the third metal ball 318 includes a copper ball center and a tin layer, and the tin layer wraps the copper ball center.

In this embodiment, the first metal ball 302, the second metal ball 312, or the third metal ball 318 may be a copper ball, may be a tin ball, or may be a copper core ball. A volume of the copper ball and a volume of the tin ball may be processed into a relatively small size. The copper core ball has lower costs than the copper ball, and the copper core ball has better electrical conductivity than the tin ball.

According to some embodiments of this application, as shown in FIG. 1 and FIG. 5, the packaging structure further includes a third dielectric layer 320 and a third wiring layer 322. The third dielectric layer 320 is disposed between the third die 210 and the fourth die 220. The third wiring layer 322 is disposed at the third dielectric layer 320, is electrically connected to the first metal ball 302, and is electrically connected to the fourth die 220.

In this embodiment, the third dielectric layer 320 is disposed between the third die 210 and the fourth die 220, the third wiring layer 322 is disposed at the third dielectric layer 320, and the third wiring layer 322 is electrically connected to both the first metal ball 302 and the fourth die 220, so that the fourth die 220 can be electrically connected to the first die 110 through the first metal ball 302, to implement bonding between the first die 110 and the fourth die 220.

According to some embodiments of this application, as shown in FIG. 1 and FIG. 5, the packaging structure further includes a third bump 324 and a fourth bump 326. The third bump 324 is disposed on a side that is of the third die 210 and that is close to the fourth die 220, and is electrically connected to the third die 210. The fourth bump 326 is disposed on a side that is of the third dielectric layer 320 and that is close to the third die 210, is electrically connected to the third wiring layer 322, and is in contact with the third bump 324.

In this embodiment, the fourth bump 326 is disposed on the side that is of the third dielectric layer 320 and that is close to the third die 210, and is electrically connected to the third wiring layer 322, so that the fourth bump 326 is electrically connected to the fourth die 220 through the third wiring layer 322. The third bump 324 is disposed on the side that is of the third die 210 and that is close to the fourth die 220, and is electrically connected to the third die 210, and the third bump 324 is in contact with the fourth bump 326, to implement bonding between the third die 210 and the fourth die 220, and implement signal transfer between the third die 210 and the fourth die 220.

Further, the third bump 324 and the fourth bump 326 may be micro-bumps, or may be copper pillars.

According to some embodiments of this application, as shown in FIG. 1 and FIG. 5, the packaging structure further includes a packaging part 328, and the packaging part 328 wraps the first packaging module 100 and the second packaging module 200.

In this embodiment, the packaging part 328 wraps the first packaging module 100 and the second packaging module 200, to implement packaging of the first packaging module 100 and the second packaging module 200. In addition to implementing protection on the first packaging module 100 and the second packaging module 200, a heat dissipation rate of the first packaging module 100 and the second packaging module 200 is improved, stability of the first packaging module 100 and the second packaging module 200 in operation is improved, and a service life of the first packaging module 100 and the second packaging module 200 is prolonged.

In addition, the packaging part 328 can effectively protect an active area of a die, to prevent the active area of the die from bumping or damage.

According to some embodiments of this application, as shown in FIG. 5, the packaging structure further includes a first colloid 330 and a second colloid 332. The first colloid 330 is filled between the first die 110 and the second die 120. The second colloid 332 is filled between the third die 210 and the fourth die 220.

In this embodiment, the first colloid 330 is filled between the first die 110 and the second die 120, and the second colloid 332 is filled between the third die 210 and the fourth die 220, to improve a packaging effect between dies, and avoid a case that a packaging material cannot be fully filled because a gap between dies of a same packaging module is relatively small.

The first colloid 330 and the second colloid 332 may be underfills.

According to some embodiments of this application, the packaging structure provided in this application may be packaged in the following packaging method.

As shown in FIG. 6, before a first metal ball 302 is arranged and a first die 110 and a second die 120 are bonded, a pad is prepared on a substrate 338. The pad is mainly configured to fasten a position of the first metal ball 302. A fifth bump 334 is prepared on the first die 110. An attach film is attached to the bottom of the first die 110, and the first die 110 is fastened to the substrate 338 when facing up.

As shown in FIG. 7, wafer-level plastic packaging is performed. A plastic packaging material is ground after being cured. Grinding is performed to expose surfaces of the first metal ball 302 and the fifth bump 334. Then, a first dielectric layer 304 and a first wiring layer 306 are prepared on the exposed surfaces, and the first wiring layer 306 implements an interconnection between the first metal ball 302 and the first die 110. Finally, a first bump 308 is prepared by using an electroplating process.

As shown in FIG. 8, the second die 120 faces downward, and is bonded to the first die 110. After bonding is completed, the first die 110 and the second die 120 are interconnected. In addition, a first colloid 330 may be, for example, filled between the first die 110 and the second die 120.

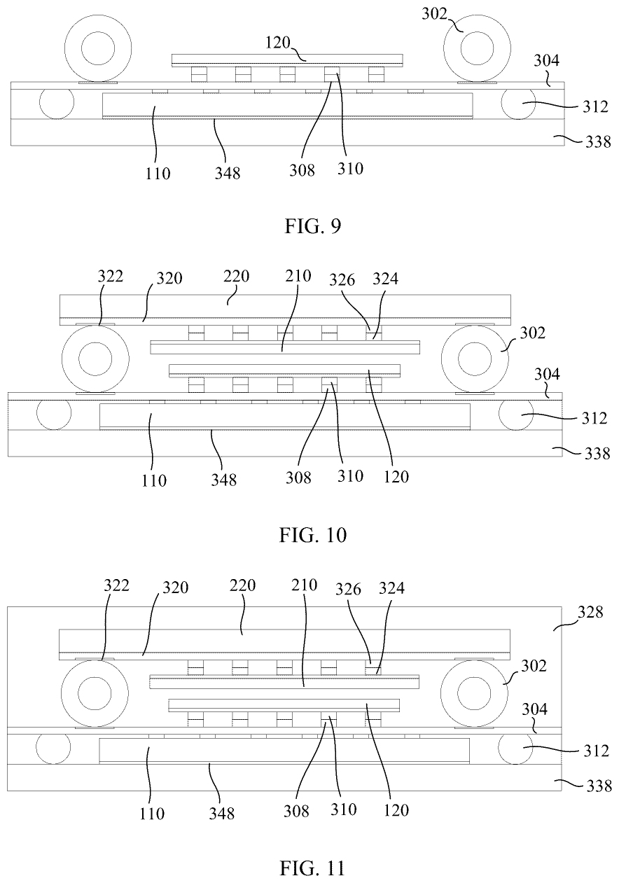

As shown in FIG. 9, the first metal ball 302 is arranged at the first wiring layer 306.

As shown in FIG. 10, a third die 210 and a fourth die 220 are modularized, and are bonded through a copper core ball. In this case, after bonding is completed, the first die 110, the second die 120, the third die 210, and the fourth die 220 are interconnected.

As shown in FIG. 11, an entire package body is plastic-packaged by using the plastic packaging material.

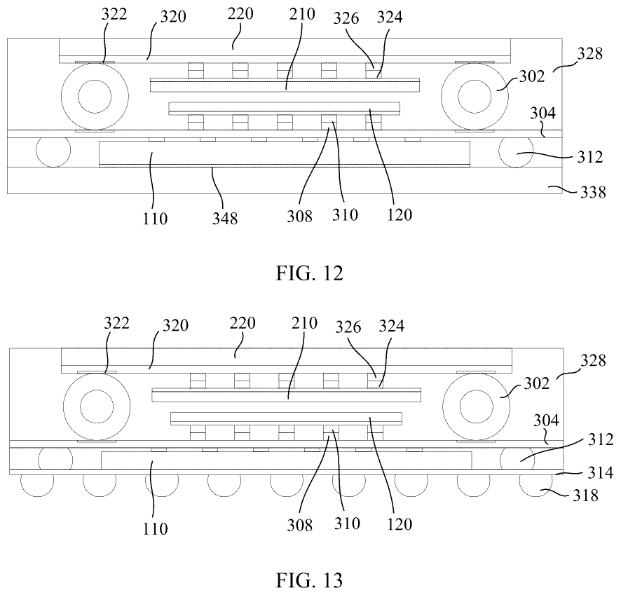

As shown in FIG. 12, the package body is ground, to thin a back substrate of the fourth die 220, and remove a back plastic packaging material.

As shown in FIG. 13, debonding is performed to remove the substrate 338, and then grinding is performed to remove a back substrate of the first die 110 and expose a second metal ball 312. Next, a third dielectric layer 320 and a third wiring layer 322 are directly prepared, and a third metal ball 318 is arranged. If the first die 110 may be further thinned, grinding may be performed to remove the back substrate and the plastic packaging material of the fourth die 220 again, until a thickness meets a requirement. Finally, dicing is performed, to dice the package body into an individual die.

An electronic device according to some embodiments of this application includes the packaging structure in any one of the foregoing embodiments. Therefore, the electronic device has all beneficial effects of the packaging structure in any one of the foregoing embodiments.

For example, the electronic device includes a mobile phone, a tablet computer, a notebook computer, a watch, or a smart wristband.

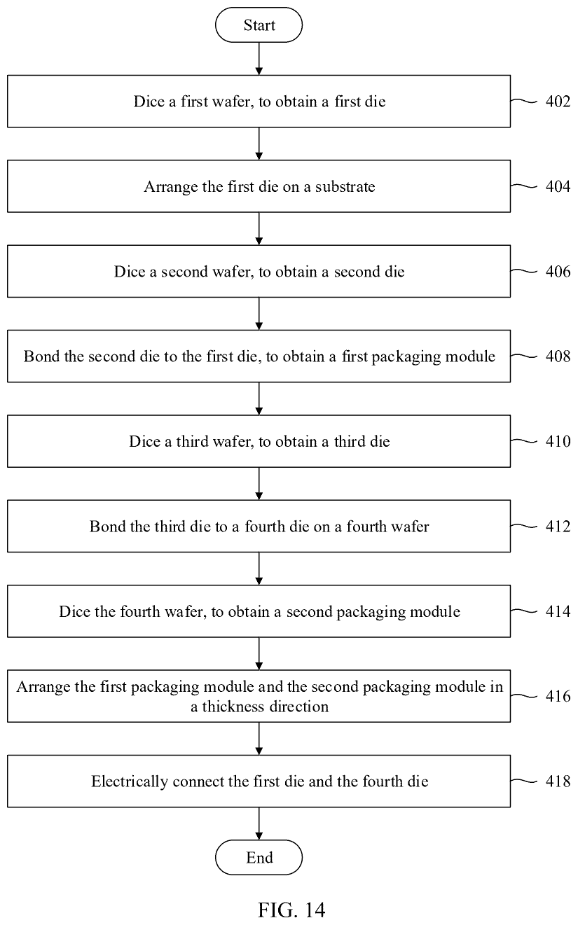

According to the packaging method in some embodiments of this application, the packaging method is used to package the packaging structure in any one of the foregoing embodiments. As shown in FIG. 14, the packaging method includes the following steps:

Step 402: Dice a first wafer, to obtain a first die.

Step 404: Arrange the first die on a substrate.

Step 406: Dice a second wafer, to obtain a second die.

Step 408: Bond the second die to the first die, to obtain a first packaging module.

Step 410: Dice a third wafer, to obtain a third die.

Step 412: Bond the third die to a fourth die on a fourth wafer.

Step 414: Dice the fourth wafer, to obtain a second packaging module.

Step 416: Arrange the first packaging module and the second packaging module in a thickness direction.

Step 418: Electrically connect the first die and the fourth die.

In this embodiment, the first wafer and the second wafer are first diced, to obtain the first die and the second die, and the third wafer is diced, to obtain the third die. The third die is bonded to a fourth die in a wafer state, and after bonding, the fourth wafer is diced, to obtain the second packaging module. Then, the first die and the second die are bonded, to obtain the first packaging module, and then the first packaging module is electrically connected to the second packaging module to obtain the packaging structure.

When the first packaging module and the second packaging module are connected, the first packaging module and the second packaging module may be connected through the first die and the fourth die on two sides in a vertical direction, to implement an electrical connection between the first packaging module and the second packaging module. When the first die and the fourth die are bonded, an electrical connection part between the first die and the fourth die may occupy space in which the second die and the third die are located, and no electrical connection part needs to be disposed between the second die and the third die, to reduce occupation of longitudinal space by an electrical connection part between the first packaging module and the second packaging module, reduce a thickness of a packaging module, reduce occupation of longitudinal space by the packaging module, and help lighten and thin the packaging module.

When bonding is performed on the first packaging module, the first die is attached to the substrate, and then the first wafer is reconstructed, so that all subsequent packaging processes are performed in the wafer state, to further improve packaging efficiency of the packaging structure.

Further, the substrate is a glass carrier.

According to some embodiments of this application, before the arranging the first packaging module and the second packaging module in a thickness direction, the packaging method further includes: preparing a first dielectric layer on the first die; preparing a first wiring layer at the first dielectric layer; arranging a first metal ball at the first wiring layer; preparing a third dielectric layer on the fourth die; and preparing a third wiring layer at the third dielectric layer; and the electrically connecting the first die and the fourth die includes: connecting the third wiring layer and the first metal ball.

In this embodiment, the first dielectric layer is located between the first die and the second die, and the first wiring layer is disposed at the first dielectric layer, is electrically connected to the first metal ball, and is electrically connected to the first die, to implement an electrical connection between the first metal ball and the first die. The third dielectric layer is disposed between the third die and the fourth die, the third wiring layer is disposed at the third dielectric layer, and the third wiring layer is electrically connected to both the first metal ball and the fourth die, so that the fourth die can be electrically connected to the first die through the first metal ball, to implement bonding between the first die and the fourth die, and further ensure that the first die can transfer data to the fourth die through the first metal ball.

According to some embodiments of this application, before the bonding the second die to the first die, the packaging method further includes: arranging a second metal ball on the substrate, where the second metal ball is electrically connected to the first wiring layer.

After the electrically connecting the first die and the fourth die, the packaging method further includes: packaging the first packaging module and the second packaging module; separating the substrate from the first packaging module; preparing a second dielectric layer on the first packaging module; preparing a second wiring layer at the second dielectric layer, where the second wiring layer is electrically connected to a second metal ball; arranging a third metal ball at the second dielectric layer, where the third metal ball is electrically connected to the second wiring layer; grinding the first packaging module and the second packaging module that are packaged; and dicing the first packaging module and the second packaging module that are packaged, to obtain the packaging structure.

In this embodiment, the second metal ball is arranged on the substrate, and the second metal ball is electrically connected to the first wiring layer, so that the second metal ball can be pre-buried in the packaging structure obtained after packaging. The second metal ball is disposed on a side that is of the first dielectric layer and that is close to the first die, and is electrically connected to the first wiring layer, so that the second metal ball is electrically connected to the first die through the first wiring layer. The second dielectric layer is disposed on a side that is of the first die and that is away from the second die, the second wiring layer is disposed at the second dielectric layer, and the second wiring layer is electrically connected to the second metal ball, so that the second wiring layer can be electrically connected to the first die. The third metal ball is disposed on a side that is of the second dielectric layer and that is away from the first die, and the third metal ball is electrically connected to the second dielectric layer, so that the third metal ball can be connected to the first die, and the first die can transfer data through the third metal ball.

In the descriptions of this specification, reference to the description of the terms “one embodiment”, “some embodiments”, “example embodiment”, “example”, “specific example”, or “some examples” means that specific features, structures, materials, or characteristics described with reference to the embodiments or examples are included in at least one embodiment or example of this application. In this specification, a schematic description of the foregoing terms does not necessarily indicate a same embodiment or example. In addition, specific features, structures, materials, or characteristics described may be incorporated in a proper manner in any one or more embodiments or examples.

Although embodiments of this application are shown and described, a person of ordinary skill in the art may understand that, various changes, modifications, replacements, and variations may be made to these embodiments without departing from the principles and objectives of this application, and the scope of this application is limited by claims and equivalents thereof.

1. A packaging structure, comprising:
a first packaging module, wherein the first packaging module comprises a first die and a second die, the first die and the second die are arranged in a thickness direction of the first die, and the first die and the second die are electrically connected; and
a second packaging module, wherein the second packaging module and the first packaging module are arranged in the thickness direction, the second packaging module comprises a third die and a fourth die, the third die and the fourth die are arranged in the thickness direction, and the third die and the fourth die are electrically connected,
wherein the fourth die and the first die are electrically connected.

2. The packaging structure according to claim 1, further comprising:
a first metal ball, wherein a first side of the first metal ball is connected to the first die, and a second side is connected to the fourth die,
wherein the first side of the first metal ball and the second side of the first metal ball are two sides that are opposite in the thickness direction.

3. The packaging structure according to claim 2, further comprising:
a first dielectric layer, wherein the first dielectric layer is disposed between the first die and the second die; and
a first wiring layer, wherein the first wiring layer is disposed at the first dielectric layer, and is electrically connected to the first metal ball and the first die.

4. The packaging structure according to claim 3, further comprising:
a first bump, wherein the first bump is disposed on a side that is of the first dielectric layer and that is close to the second die, and is electrically connected to the first wiring layer; and
a second bump, wherein the second bump is disposed on a side that is of the second die and that is close to the first die, is electrically connected to the second die, and is in contact with the first bump.

5. The packaging structure according to claim 3, further comprising:
a second metal ball, wherein the second metal ball is disposed on a side that is of the first dielectric layer and that is close to the first die, and is electrically connected to the first wiring layer;
a second dielectric layer, wherein the second dielectric layer is disposed on a side that is of the first die and that is away from the second die;
a second wiring layer, wherein the second wiring layer is disposed at the second dielectric layer, and is electrically connected to the second metal ball; and
a third metal ball, wherein the third metal ball is disposed on a side that is of the second dielectric layer and that is away from the first die, and is electrically connected to the second dielectric layer.

6. The packaging structure according to claim 5, wherein at least one of the first metal ball, the second metal ball, or the third metal ball is a copper ball; or
at least one of the first metal ball, the second metal ball, or the third metal ball is a tin ball; or
at least one of the first metal ball, the second metal ball, or the third metal ball comprises a copper ball center and a tin layer, and the tin layer wraps the copper ball center.

7. The packaging structure according to claim 2, further comprising:
a third dielectric layer, wherein the third dielectric layer is disposed between the third die and the fourth die; and
a third wiring layer, wherein the third wiring layer is disposed at the third dielectric layer, is electrically connected to the first metal ball, and is electrically connected to the fourth die.

8. The packaging structure according to claim 7, further comprising:
a third bump, wherein the third bump is disposed on a side that is of the third die and that is close to the fourth die, and is electrically connected to the third die; and
a fourth bump, wherein the fourth bump is disposed on a side that is of the third dielectric layer and that is close to the third die, is electrically connected to the third wiring layer, and is in contact with the third bump.

9. The packaging structure according to claim 1, further comprising:
a packaging part, wherein the packaging part wraps the first packaging module and the second packaging module.

10. The packaging structure according to claim 1, further comprising:
a first colloid, wherein the first colloid is filled between the first die and the second die; and
a second colloid, wherein the second colloid is filled between the third die and the fourth die.

11. An electronic device, comprising:
a packaging structure, comprising:
a first packaging module, wherein the first packaging module comprises a first die and a second die, the first die and the second die are arranged in a thickness direction of the first die, and the first die and the second die are electrically connected; and
a second packaging module, wherein the second packaging module and the first packaging module are arranged in the thickness direction, the second packaging module comprises a third die and a fourth die, the third die and the fourth die are arranged in the thickness direction, and the third die and the fourth die are electrically connected,
wherein the fourth die and the first die are electrically connected.

12. The electronic device according to claim 11, wherein the packaging structure further comprises:
a first metal ball, wherein a first side of the first metal ball is connected to the first die, and a second side is connected to the fourth die,
wherein the first side of the first metal ball and the second side of the first metal ball are two sides that are opposite in the thickness direction.

13. The electronic device according to claim 12, wherein the packaging structure further comprises:
a first dielectric layer, wherein the first dielectric layer is disposed between the first die and the second die; and
a first wiring layer, wherein the first wiring layer is disposed at the first dielectric layer, and is electrically connected to the first metal ball and the first die.

14. The electronic device according to claim 13, wherein the packaging structure further comprises:
a first bump, wherein the first bump is disposed on a side that is of the first dielectric layer and that is close to the second die, and is electrically connected to the first wiring layer; and
a second bump, wherein the second bump is disposed on a side that is of the second die and that is close to the first die, is electrically connected to the second die, and is in contact with the first bump.

15. The electronic device according to claim 13, wherein the packaging structure further comprises:
a second metal ball, wherein the second metal ball is disposed on a side that is of the first dielectric layer and that is close to the first die, and is electrically connected to the first wiring layer;
a second dielectric layer, wherein the second dielectric layer is disposed on a side that is of the first die and that is away from the second die;
a second wiring layer, wherein the second wiring layer is disposed at the second dielectric layer, and is electrically connected to the second metal ball; and
a third metal ball, wherein the third metal ball is disposed on a side that is of the second dielectric layer and that is away from the first die, and is electrically connected to the second dielectric layer.

16. The electronic device according to claim 15, wherein at least one of the first metal ball, the second metal ball, or the third metal ball is a copper ball; or
at least one of the first metal ball, the second metal ball, or the third metal ball is a tin ball; or
at least one of the first metal ball, the second metal ball, or the third metal ball comprises a copper ball center and a tin layer, and the tin layer wraps the copper ball center.

17. The electronic device according to claim 12, wherein the packaging structure further comprises:
a third dielectric layer, wherein the third dielectric layer is disposed between the third die and the fourth die; and
a third wiring layer, wherein the third wiring layer is disposed at the third dielectric layer, is electrically connected to the first metal ball, and is electrically connected to the fourth die.

18. A packaging method to make a packaging structure, comprising:
dicing a first wafer, to obtain a first die;
arranging the first die on a substrate;
dicing a second wafer, to obtain a second die;
bonding the second die to the first die, to obtain a first packaging module;
dicing a third wafer, to obtain a third die;
bonding the third die to a fourth die on a fourth wafer;
dicing the fourth wafer, to obtain a second packaging module;
arranging the first packaging module and the second packaging module in a thickness direction; and
electrically connecting the first die and the fourth die.

19. The packaging method according to claim 18, wherein before the arranging the first packaging module and the second packaging module in the thickness direction, the packaging method further comprises:
preparing a first dielectric layer on the first die;
preparing a first wiring layer at the first dielectric layer;
arranging a first metal ball at the first wiring layer;
preparing a third dielectric layer on the fourth die; and
preparing a third wiring layer at the third dielectric layer,
wherein the electrically connecting the first die and the fourth die comprises: connecting the third wiring layer and the first metal ball.

20. The packaging method according to claim 19, wherein before the bonding the second die to the first die, the packaging method further comprises:
arranging a second metal ball on the substrate, wherein the second metal ball is electrically connected to the first wiring layer, and
wherein after the electrically connecting the first die and the fourth die, the packaging method further comprises:
packaging the first packaging module and the second packaging module;
separating the substrate from the first packaging module;
preparing a second dielectric layer on the first packaging module;
preparing a second wiring layer at the second dielectric layer, wherein the second wiring layer is electrically connected to a second metal ball;
arranging a third metal ball at the second dielectric layer, wherein the third metal ball is electrically connected to the second wiring layer;
grinding the first packaging module and the second packaging module that are packaged; and
dicing the first packaging module and the second packaging module that are packaged, to obtain the packaging structure.
